(19) United States
(12) Patent Application Publication
(10) Pub. No.: US 2026/0105228 A1
(43) Pub. Date: Apr. 16, 2026

(54) ELECTRONIC DESIGN SUPPORTING DEVICE AND ELECTRONIC DESIGN SUPPORTING METHOD

(71) Applicant: Hitachi, Ltd., Tokyo (JP)

(72) Inventor: Takuma NISHIMOTO, Tokyo (JP)

(21) Appl. No.: 19/270,707

(22) Filed: Jul. 16, 2025

(30) Foreign Application Priority Data
Oct. 10, 2024 (JP) 2024-178270

(51) Int. Cl. G06F 30/31; G06F 40/35

(52) U.S. Cl. CPC G06F 30/31; G06F 40/35

(57) ABSTRACT

An electronic design supporting device includes a link data conversion unit that converts design data of a circuit constituting an apparatus into link data, a text conversion unit that converts the link data into a circuit text, a vector conversion unit that converts the circuit text into circuit vector data, an inquiry statement reception unit that receives an inquiry statement regarding the circuit, a prompt generation unit that generates a prompt corresponding to the inquiry statement, a context generation unit that generates a context by reading the circuit vector data corresponding to the circuit and related to a content of the inquiry statement, and an answer statement acquisition unit that acquires an answer statement corresponding to the inquiry statement by inputting the prompt and the context to a language processing model.

### BACKGROUND OF THE INVENTION

### 1. Field of the Invention

The present invention relates to an electronic design supporting device and an electronic design supporting method.

### 2. Description of the Related Art

Regarding a technique for supporting designing a circuit constituting an apparatus, for example, JP 2023-115553 A describes “a learning device including: a first setting unit that sets, from a plurality of pieces of learning data in which a circuit feature value representing a feature of a circuit, circuit topology information representing a circuit topology, and an element value of an element constituting the circuit are associated with each other, first train data representing a combination of the circuit feature value and the circuit topology information; a first generation unit that generates a first trained model by training a machine learning model for outputting the circuit topology information from the circuit feature value based on the first train data set by the first setting unit; a second setting unit that sets, from the plurality of pieces of learning data, second train data representing a combination of the circuit feature value and the element value; and a second generation unit that generates a second trained model by training a machine learning model for outputting the element value from the circuit feature value based on the second train data set by the second setting unit” and “an electronic design supporting device including: a circuit acquisition unit that acquires circuit topology information corresponding to a requested circuit feature value representing a requested feature of the circuit by inputting the requested circuit feature value to the first trained model generated by the learning device; an initial value generation unit that generates an initial value of an element value of the circuit corresponding to the requested circuit feature value by inputting the requested circuit feature value to the second trained model generated by the learning device; an element value generation unit that generates the element value corresponding to the requested circuit feature value by executing a predetermined optimization calculation using the initial value acquired by the initial value generation unit; and a result acquisition unit that stores, in a storage unit, the circuit topology information corresponding to the requested circuit feature value and acquired by the circuit acquisition unit and the element value generated by the element value generation unit in association with each other”.

### SUMMARY OF THE INVENTION

According to the electronic design supporting device described in JP 2023-115553 A, a circuit topology satisfying a required specification and an element value thereof can be accurately determined. However, in recent electronic design sites, an increase in man-hours required for design caused due to an increase in design constraints and rework caused by missing or overlooking design constraints have become problems. Therefore, designers need to check whether circuits constituting designed apparatuses meet predetermined specifications and constraints, but until now, there has been no method established for easily checking this.

The present invention has been made in view of the foregoing points, and an object of the present invention is to enable a designer or the like to easily confirm whether a designed circuit meets predetermined specifications and constraints.

The present application includes a plurality of means for solving at least some of the aforementioned problems, examples of which are as follows.

In order to solve the aforementioned problems, an electronic design supporting device according to an aspect of the present invention is an electronic design supporting device that supports designing a circuit constituting an apparatus, the electronic design supporting device including: a link data conversion unit that converts design data of the circuit into link data representing a connection relationship between parts arranged in the circuit; a text conversion unit that converts the link data together with at least one of a specification statement and a constraint statement related to the circuit into a text to generate a circuit text; a vector conversion unit that converts the circuit text into a vector to generate circuit vector data; a circuit vector database that stores the circuit vector data; an inquiry statement reception unit that receives an inquiry statement regarding the circuit; a prompt generation unit that generates a prompt corresponding to the inquiry statement; a context generation unit that generates a context by reading the circuit vector data corresponding to the circuit and related to a content of the inquiry statement from the circuit vector database; and an answer statement acquisition unit that acquires an answer statement corresponding to the inquiry statement by inputting the prompt and the context to a language processing model.

According to the present invention, a designer or the like can easily check whether a designed circuit meets predetermined specifications and constraints. As a result, it is possible to support designing the circuit, and it is possible to prevent an increase in man-hours required for design and rework caused by missing or overlooking design constraints.

Other problems, configurations, and effects that are not described above will be apparent from the following description of embodiments.

### BRIEF DESCRIPTION OF THE DRAWINGS

FIG. 1 is a diagram for explaining an outline of a series of processes performed by an electronic design supporting device according to an embodiment of the present invention;

FIG. 2 is a diagram illustrating an example of a configuration of an electronic design supporting system according to an embodiment of the present invention;

FIG. 3 is a flowchart illustrating an example of an electronic design supporting process performed by the electronic design supporting system;

FIG. 4 is a circuit diagram illustrating an example of a configuration of a circuit constituting a designed apparatus;

FIG. 5 is a circuit diagram illustrating an example of a configuration of an A unit;

FIG. 6 is a circuit diagram illustrating an example of a configuration of a board A;

FIG. 7 is a diagram illustrating an example of a graph data structure corresponding to the circuit of FIG. 4;

FIG. 8 is a diagram illustrating an example of a graph data structure corresponding to the A unit of FIG. 5;

FIG. 9 is a diagram illustrating an example of a graph data structure corresponding to the board A of FIG. 6;

FIG. 10 is a flowchart illustrating an example of a hierarchical structure circuit text conversion process;

FIG. 11 is a diagram for explaining a database method that is an example of a method of reading specification/constraint data by a circuit text conversion process;

FIG. 12 is a diagram illustrating an example of a result of reading specification/constraint data; and

FIG. 13 is a diagram for explaining a retrieval augmented generation (RAG) method that is an example of a method of reading specification/constraint data by a circuit text conversion process.

### DESCRIPTION OF THE PREFERRED EMBODIMENTS

Hereinafter, an embodiment of the present invention will be described with reference to the drawings. An embodiment is an example for describing the present invention, and omission and simplification are appropriately made for clarity of description. The present invention can be implemented in various other forms. Unless otherwise specified, each component may be singular or plural. Positions, sizes, shapes, ranges, and the like of the components illustrated in the drawings may not represent actual positions, sizes, shapes, ranges, and the like in order to facilitate understanding of the invention. Note that, in all the drawings for describing the embodiment, the same members are denoted by the same reference numerals in principle, and repeated description thereof will be omitted. In addition, in the following embodiment, the components (including elemental steps and the like) are not necessarily essential, unless otherwise specified or unless considered to be obviously essential in principle. In addition, when an expression “including A”, “comprising A”, “having A”, or “containing A” is used, this does not preclude presence of other elements, unless it is particularly specified that only the element is included. Similarly, in the following embodiments, when shapes, positional relationships, and the like of the components and the like are mentioned, they include shapes and the like substantially approximate or similar thereto, unless otherwise specified or unless considered to be obviously essential in principle. In addition, “acquisition” at least includes, as specific examples, generation, calculation, or reception by a subject from the outside.

### <Outline of Series of Processes Performed by Electronic Design Supporting Device According to Embodiment of Present Invention>

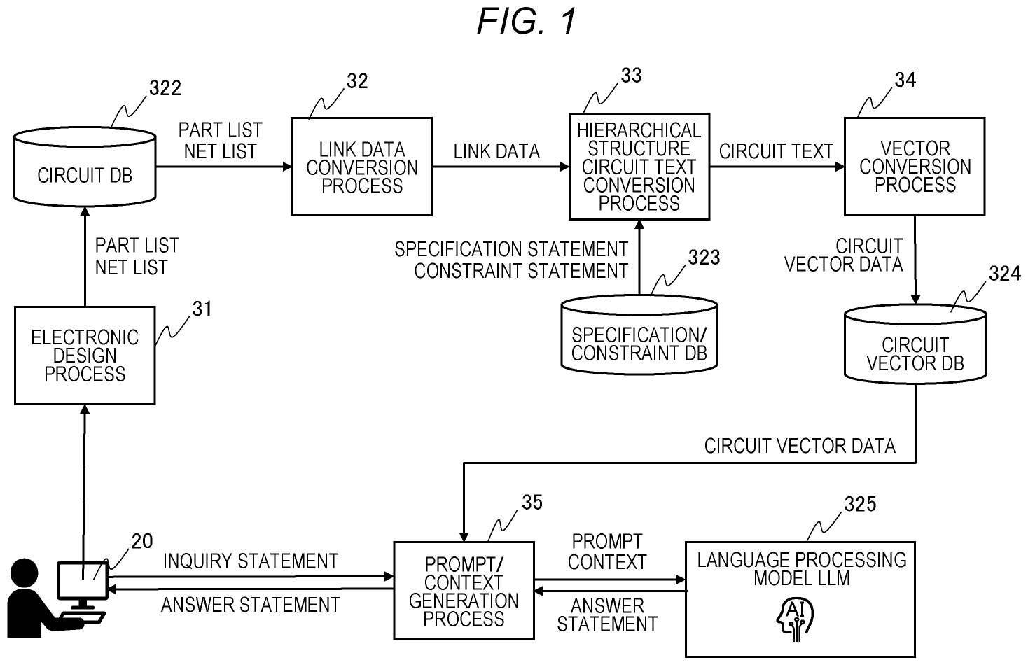

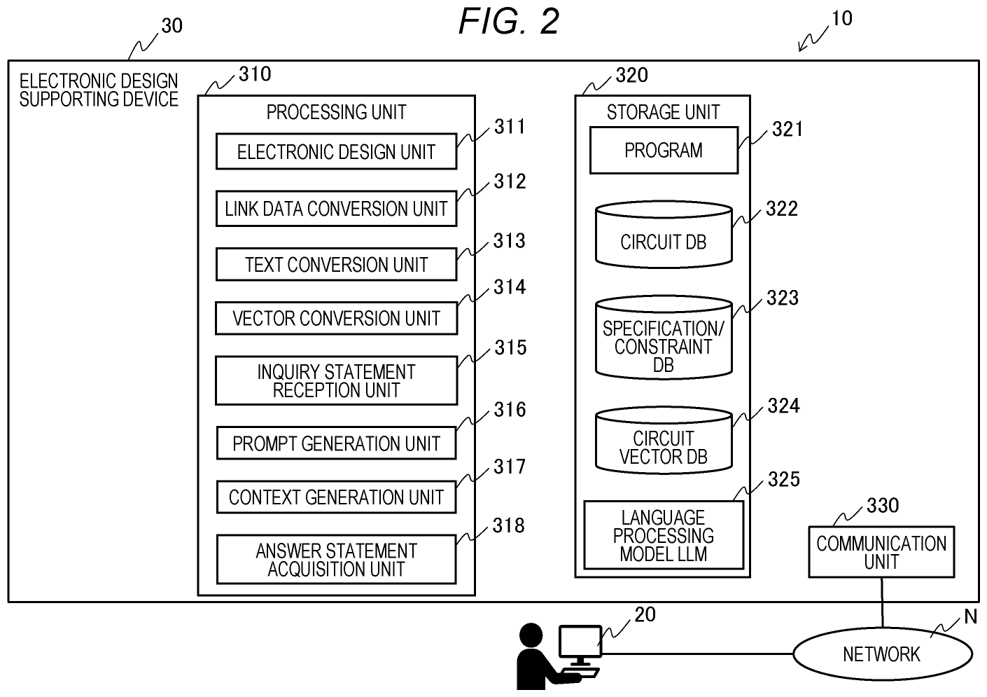

FIG. 1 illustrates an outline of a series of processes performed by an electronic design supporting device 30 (FIG. 2) according to an embodiment of the present invention. The series of processes performed by the electronic design supporting device 30 includes an electronic design process 31, a link data conversion process 32, a hierarchical structure circuit text conversion process 33, a vector conversion process 34, and a prompt/context generation process 35.

In the electronic design process 31, a circuit constituting an apparatus is designed based on an operation input from a designer or the like (hereinafter, referred to as a user) using a terminal device 20, and a part list in which parts (units, boards, electronic elements, etc.) provided in the circuit are listed and a net list indicating a connection state of each part are stored in a circuit DB 322 as design data that is a processing result. Note that the electronic design process 31 can be realized by software having functions similar to those of existing electronic design software tools.

In the link data conversion process 32, the part list and the net list corresponding to the circuit constituting the designed apparatus are read from the circuit DB 322, and the part list and the net list are converted into link data.

In the hierarchical structure circuit text conversion process 33, a graph data structure corresponding to layers of the circuit constituting the apparatus is extracted from the link data, at least one of a related specification statement and a related constraint statement is read from a specification/constraint DB 323, and a circuit text obtained by converting the link data into a text is generated based on the graph data structure, the specification statement, and the constraint statement. A method of reading the specification statement and the constraint statement from the specification/constraint DB 323 will be described later.

In the vector conversion process 34, circuit vector data is generated in a data format in which a language processing model 325 can access the circuit text by employing an existing vector conversion method such as Chromadb, Lancedb, Pinecone, or the like, and the circuit vector data is stored in a circuit vector DB 324.

In the prompt/context generation process 35, a prompt suitable for an input to the language processing model 325 corresponding to an inquiry statement regarding the circuit constituting the apparatus from the user is generated. In addition, in the prompt/context generation process 35, a context is generated by retrieving and reading circuit vector data highly relevant to the inquiry statement from the circuit vector DB 324.

The language processing model 325 generates and outputs an answer statement in a natural language in response to the inquiry from the user based on the prompt (inquiry statement) and the context. Note that the context can be defined as being included in the prompt, but the context will be separately described in the present application.

The generated answer statement is transmitted to the terminal device 20 and presented to the user from which the inquiry has been sent. As a result, the user can easily grasp the details of the entire designed apparatus and each circuit, and it is possible to reduce the man-hours required for design and prevent rework caused by missing or overlooking design constraints.

### <Example of Configuration of Electronic Design Supporting System 10 According to Embodiment of Present Invention>

FIG. 2 illustrates an example of a configuration of an electronic design supporting system 10 according to an embodiment of the present invention. The electronic design supporting system 10 includes a terminal device 20 and an electronic design supporting device 30.

The terminal device 20 includes, for example, a general computer such as a personal computer. The terminal device 20 is connected to the electronic design supporting device 30 via a network N to communicate various types of data. The network N is a bidirectional communication network represented by the Internet.

The electronic design supporting device 30 is realized by, for example, a general computer such as a personal computer or a server computer. The computer includes a processor such as a central processing unit (CPU), a memory such as a dynamic random access memory (DRAM), a storage such as a hard disk drive (HDD) or a solid state drive (SSD), an input device such as a keyboard, a mouse, or a media drive, an output device such as a display, and a communication module such as an Ethernet (trademark) card or a Wi-Fi (trademark) adapter.

The electronic design supporting device 30 may be realized by one physical or logical computer, or may be realized by two or more physical or logical computers. The two or more physical or logical computers may be arranged on the network N in a distributed manner.

The electronic design supporting device 30 includes functional blocks for a processing unit 310, a storage unit 320, and a communication unit 330.

The processing unit 310 is realized by a processor of a computer constituting the electronic design supporting device 30. The processing unit 310 controls the entire electronic design supporting device 30. The processing unit 310 (processor) executes a program 321 in the storage unit 320 to realize functional blocks for an electronic design unit 311, a link data conversion unit 312, a text conversion unit 313, a vector conversion unit 314, an inquiry statement reception unit 315, a prompt generation unit 316, a context generation unit 317, and an answer statement acquisition unit 318. Note that the electronic design unit 311 may be realized by executing an existing electronic design software tool.

The electronic design unit 311 executes the electronic design process 31 (FIG. 1) based on an operation input from a designer. The link data conversion unit 312 executes the link data conversion process 32 (FIG. 1). The text conversion unit 313 executes the hierarchical structure circuit text conversion process 33 (FIG. 1). The vector conversion unit 314 executes the vector conversion process 34 (FIG. 1).

The inquiry statement reception unit 315 receives a user's inquiry statement from the terminal device 20 via the communication unit 330. The prompt generation unit 316 and the context generation unit 317 execute the prompt/context generation process 35 (FIG. 1). The answer statement acquisition unit 318 inputs a prompt and a context to the language processing model 325, acquires an answer statement corresponding to the inquiry statement from the language processing model 325, and transmits the answer statement to the terminal device 20 via the communication unit 330. As described above, in the present embodiment, the language processing model 325 is used by a retrieval augmented generation (RAG) method.

The storage unit 320 is realized by a memory and a storage of a computer constituting the electronic design supporting device 30. The storage unit 320 stores a program 321, a circuit DB 322, a specification/constraint DB 323, a circuit vector DB 324, and a language processing model 325. Note that information and data other than those described above may be stored in the storage unit 320.

The program 321 is a program for causing a computer constituting the electronic design supporting device 30 to operate as the electronic design supporting device 30. The circuit DB 322 stores a part list and a net list as design data for the circuit constituting the designed apparatus. The specification/constraint DB 323 stores data regarding specifications and constraints of apparatuses and circuits such as specifications, design documents, and data seeds for the apparatuses and the circuits. The circuit vector DB 324 stores circuit vector data obtained by converting a circuit text into a vector.

The language processing model 325 is, for example, a large-scale language model (LLM) (or generative AI including the LLM) that is an exclusively-constructed or existing service. When an inquiry statement from the user and a context are input to the language processing model 325, the language processing model 325 generates and outputs an answer statement to the inquiry statement in a natural language.

Note that the language processing model 325 may be arranged, for example, in a server or the like connected to the network N, rather than being stored in the storage unit 320 of the electronic design supporting device 30.

### <Electronic Design Supporting Process Performed by Electronic Design Supporting System 10>

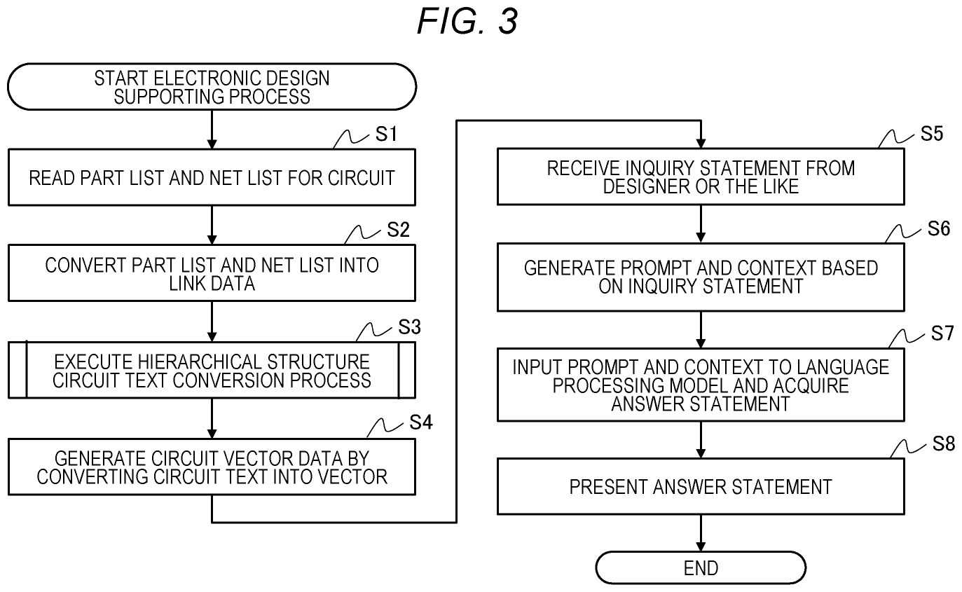

FIG. 3 is a flowchart illustrating an example of an electronic design supporting process performed by the electronic design supporting system 10.

The electronic design supporting process is started, for example, in response to a predetermined operation from a user who designs a circuit constituting the apparatus using the terminal device 20. Note that, as a premise, it is assumed that a part list and a net list corresponding to a circuit constituting the designed apparatus are stored in the circuit DB 322.

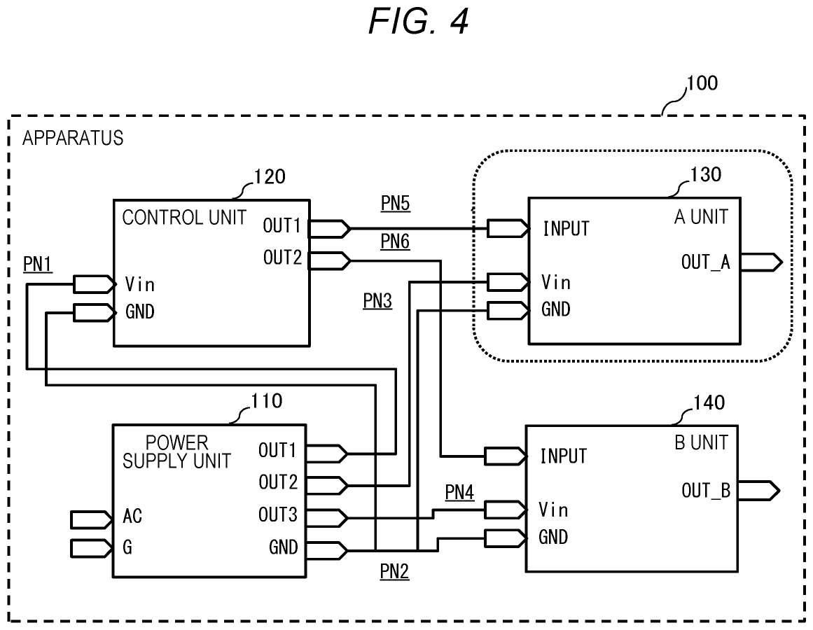

FIGS. 4 to 6 illustrate an example of a circuit constituting an apparatus 100 in which the part list and the net list are stored in the circuit DB 322. The circuit constituting the apparatus 100 includes an upper layer including one or more units, a middle layer including one or more boards, and a lower layer including one or more electronic elements.

As illustrated in FIG. 4, the upper layer of the circuit constituting the apparatus 100 is configured by connecting a power supply unit 110, a control unit 120, an A unit 130, and a B unit 140 to each other via wirings PN1 to PN6.

For example, when focused on the A unit 130, an INPUT terminal of the A unit 130 is connected to an OUT1 terminal of the control unit 120 via the wiring PN5. A Vin terminal of the A unit 130 is connected to an OUT2 terminal of the power supply unit 110 via the wiring PN3. A GND terminal of the A unit 130 is connected to a GND terminal of each of the power supply unit 110, the control unit 120, and the B unit 140 via the wiring PN2.

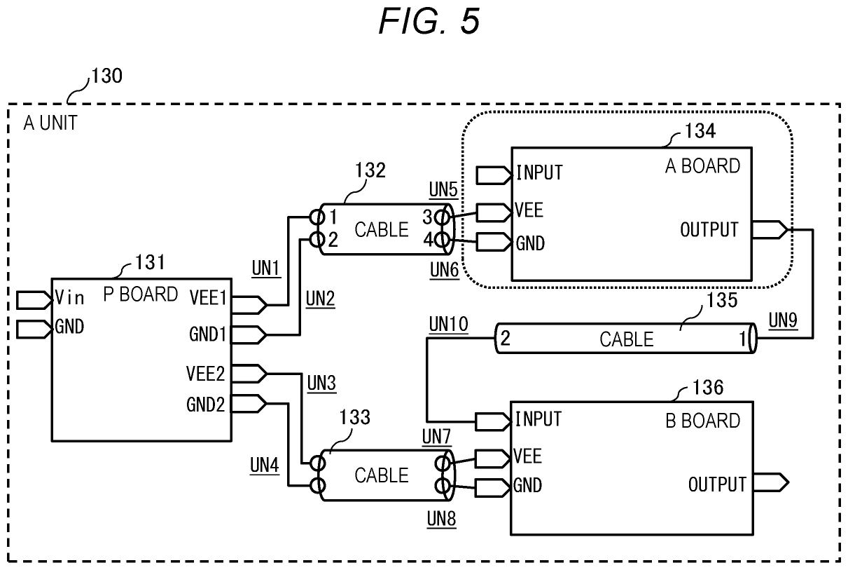

As illustrated in FIG. 5, the middle layer corresponding to the A unit 130 is configured by connecting a P board 131, cables 132 and 133, an A board 134, a cable 135, and a B board 136 to each other via wirings UN1 to UN10.

For example, when focused on the A board 134, a VEE terminal of the A board 134 is connected to a #3 terminal of the cable 132 via the wiring UN5. A GND terminal of the A board 134 is connected to a #4 terminal of the cable 132 via the wiring UN6. An OUTPUT terminal of the A board 134 is connected to a #1 terminal of the cable 135 via the wiring UN9.

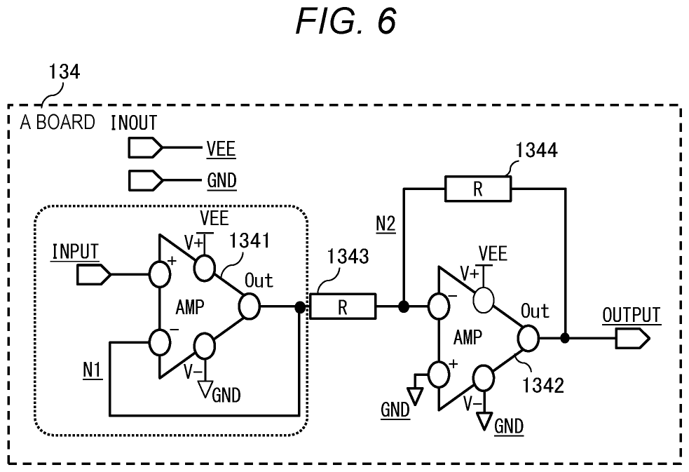

As illustrated in FIG. 6, the lower layer corresponding to the A board 134 is configured by connecting amplifiers (AMP) 1341 and 1342 and resistors (R) 1343 and 1344 to each other via wirings N1 and N2.

For example, when focused on the amplifier 1341, a V+ terminal of the amplifier 1341 is connected to VEE. A V− terminal of the amplifier 1341 is connected to GND. An OUT terminal of the amplifier 1341 is connected to the resistor 1343 and a − terminal of the amplifier 1341 via the wiring N1. A + terminal of the amplifier 1341 is connected to INPUT.

Hereinafter, the description will continue using the circuit diagrams of the respective layers of the apparatus 100 illustrated in FIGS. 4 to 6 as an example. Referring back to FIG. 3, the description will continue. First, the link data conversion unit 312 reads the part list and the net list corresponding to the circuit constituting the designed apparatus 100 from the circuit DB 322 (step S1), and converts the part list and the net list into link data (step S2).

The link data represents a connection relationship between parts arranged in the circuit for each layer of the circuit constituting the apparatus 100. More specifically, the link data is represented by a graph data structure in which parts arranged in the layers, terminals provided in the parts, and wirings are represented by nodes, and connection states between the parts, the terminals, and the wirings are represented by edges.

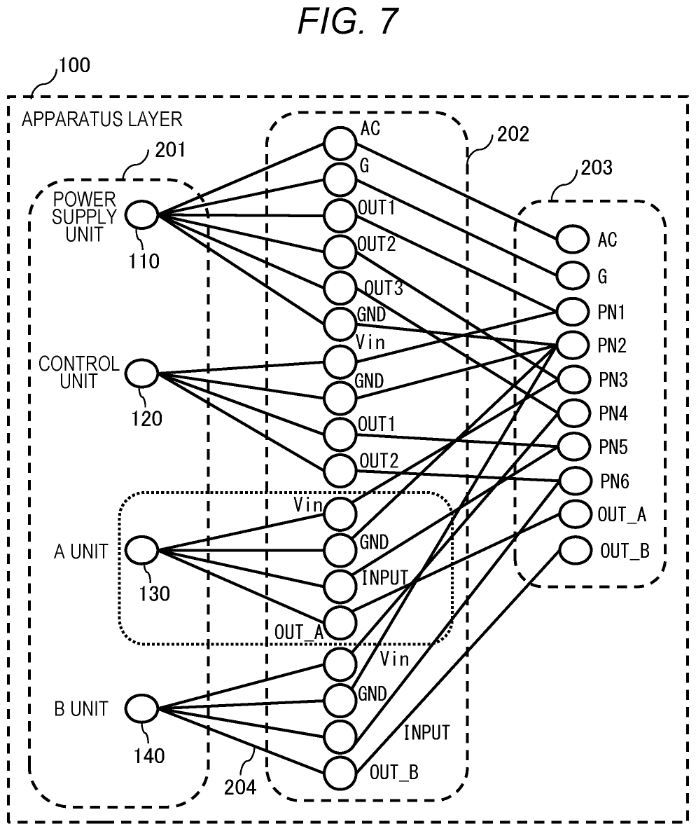

FIG. 7 illustrates a graph data structure corresponding to the circuit constituting the apparatus 100 illustrated in FIG. 4. That is, in a graph data structure corresponding to an apparatus layer, which is an upper layer, each of the power supply unit 110, the control unit 120, the A unit 130, and the B unit 140 is represented by a part node 201, each terminal of each unit is represented by a terminal node 202, each of the wirings PN1 to PN6 and the like is represented by a wiring node 203, and a connection between the units is represented by an edge 204 between the nodes.

For example, when focused on the nodes in the A unit 130, a terminal node for the Vin terminal of the A unit 130 is connected to a terminal node for the OUT2 terminal of the power supply unit 110 via a wiring node for the wiring PN3. A terminal node for the GND terminal of the A unit 130 is connected to a terminal node for the GND terminal of each of the power supply unit 110, the control unit 120, and the B unit 140 via a wiring node for the wiring PN2. A terminal node for the INPUT terminal of the A unit 130 is connected to a terminal node for the OUT1 terminal of the control unit 120 via a wiring node for the wiring PN5. A terminal node for the OUT A terminal of the A unit 130 is connected to a wiring node for the wiring OUT A.

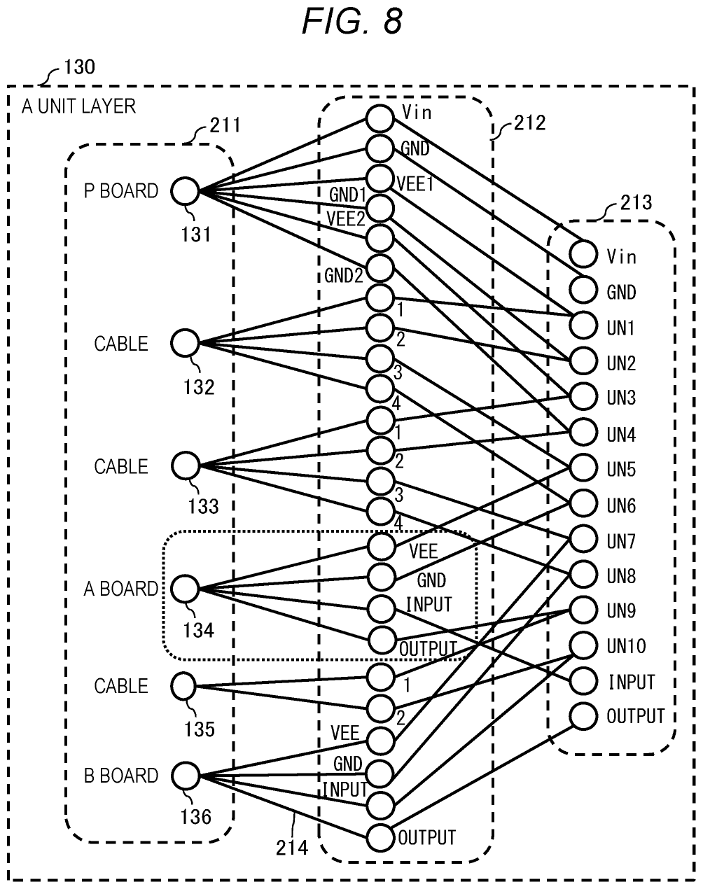

FIG. 8 illustrates a graph data structure corresponding to the middle layer including the A unit 130 illustrated in FIG. 5. That is, in a graph data structure corresponding to an A unit layer, which is a middle layer, each of the P board 131, the cables 132 and 133, the A board 134, the cable 135, and the B board 136 is represented by a part node 211, each terminal of each board or cable is represented by a terminal node 212, each of the wirings UN1 to UN10 and the like is represented by a wiring node 213, and a connection between the boards is represented by an edge 214 between the nodes.

For example, when focused on the nodes in the A board 134, a terminal node for the VEE terminal of the A board 134 is connected to a terminal node for the #3 terminal of the cable 132 via a wiring node for the wiring UN5. A terminal node for the GND terminal of the A board 134 is connected to a terminal node for the #4 terminal of the cable 132 via a wiring node for the wiring UN6. A terminal node for the INPUT terminal of the A board 134 is connected to a wiring node for INPUT. A terminal node for the OUTPUT terminal of the A board 134 is connected to a terminal node for the #1 terminal of the cable 135 via a wiring node for the wiring UN9.

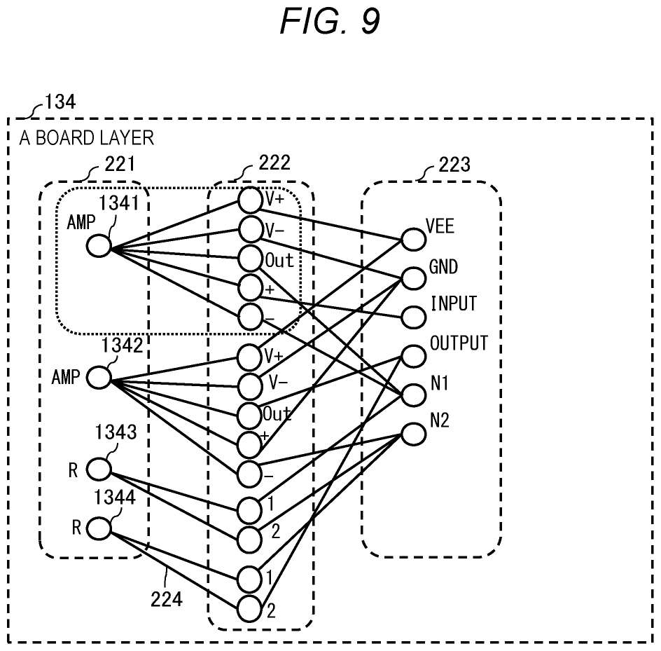

FIG. 9 illustrates a graph data structure of the lower layer including the A board 134 illustrated in FIG. 6. That is, in a graph data structure corresponding to an A board layer, which is a lower layer, each of the amplifiers 1341 and 1342 and the resistors 1343 and 1344 is represented by a part node 221, a terminal of each of the amplifiers and the resistors is represented by a terminal node 222, each of the wirings N1 and N2 and the like is represented by a wiring node 223, and a connection between the amplifiers and the like is represented by an edge 224 between the nodes.

For example, when focused on the nodes in the amplifier 1341, a terminal node for the V+ terminal of the amplifier 1341 is connected to a wiring node for VEE. A terminal node for the V− terminal of the amplifier 1341 is connected to a wiring node for GND. A terminal node for the OUT terminal of the amplifier 1341 is connected to a terminal node for the #1 terminal of the resistor 1343 and a terminal node for the − terminal of the amplifier 1341 via a wiring node for the wiring N1. A terminal node for the + terminal of the amplifier 1341 is connected to a wiring node for INPUT.

Hereinafter, the description will continue using the graph data structures of the respective layers of the circuit constituting the apparatus 100 illustrated in FIGS. 7 to 9 as examples of link data. However, the graph data structures illustrated in FIGS. 7 to 9 are merely examples of link data, and the data format of the link data is not limited to the graph data structure.

Referring back to FIG. 3, the description will continue. Next, the text conversion unit 313 executes the hierarchical structure circuit text conversion process for converting the link data into a text to generate a circuit text (step S3).

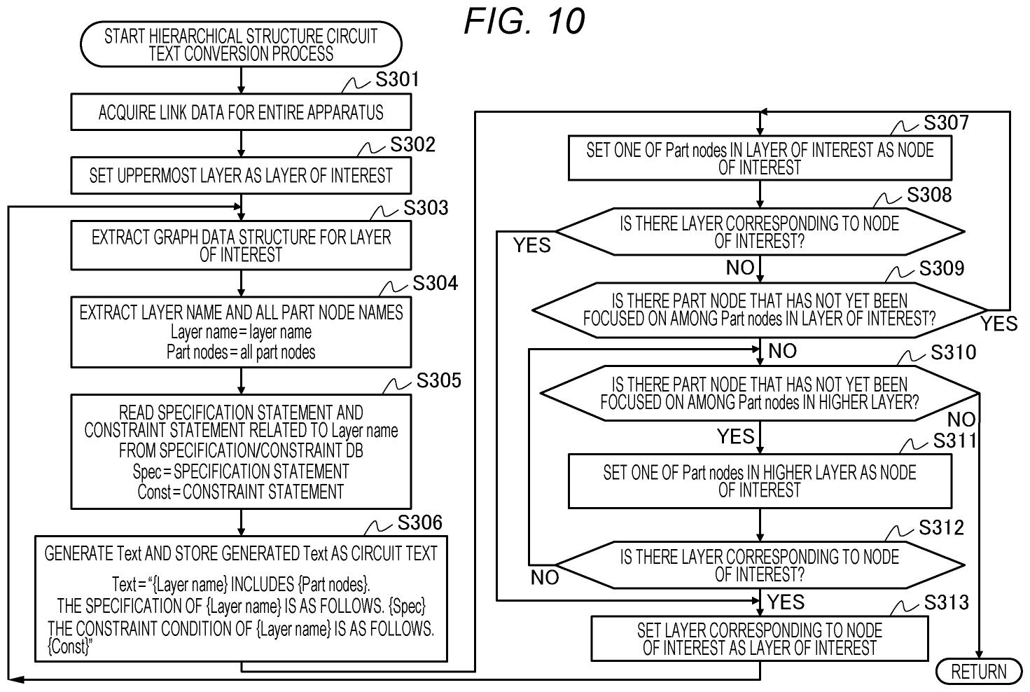

FIG. 10 is a flowchart illustrating an example of a hierarchical structure circuit text conversion process.

First, the text conversion unit 313 acquires link data for the entire circuit constituting the apparatus 100 (step S301). Next, the text conversion unit 313 sets the uppermost layer of the link data as a layer of interest (step S302) and extracts a graph data structure corresponding to the layer of interest (step S303). In this case, focusing on an upper layer that is the uppermost layer of the circuit constituting the apparatus 100, the graph data structure (FIG. 7) corresponding to the upper layer is extracted.

Next, the text conversion unit 313 extracts a layer name and all part node names from the graph data structure, and defines Layer name and Part nodes as follows (step S304).

$$Layer name = extracted layer name$$

$$Part nodes = all extracted part node names ( list of part node names )$$

Next, the text conversion unit 313 reads a specification statement and a constraint statement related to Layer name=layer name from the specification/constraint DB 323, and defines Spec and Const as follows (step S305). A method of reading the specification statement and the constraint statement will be described later.

$$Spec = read specification statement$$

$$Const = read constraint statement$$

Next, the text conversion unit 313 generates the following Text using Layer name, Part nodes, Spec, and Const defined in steps S304 and S305. Specifically, for example, a layer name defined as Layer name is inserted into {Layer name} in Text. Then, for example, the generated Text is temporarily stored in the storage unit 320 as the circuit text (step S306).

$$Text = {}^{″} \{ Layer name \} includes \{ Part nodes \} .$$

The specification of {Layer name} is as follows.

### {Spec}

Further, the constraint condition of {Layer name} is as follows. {Const}”

Next, the text conversion unit 313 sets one of the part nodes in the layer of interest as a node of interest (step S307). In this case, since the apparatus layer (FIG. 7), which is an upper layer, is a layer of interest, one of the four part nodes 201 is set as a node of interest. Here, for example, it is assumed that a part node corresponding to the A unit 130 is set as a node of interest.

Next, the text conversion unit 313 determines whether there is a layer corresponding to the node of interest (step S308). When it is determined that there is a layer corresponding to the node of interest (YES in step S308), the process proceeds to step S313. In this case, since there is an A unit layer (FIG. 8) corresponding to the A unit 130, the process proceeds to step S313.

Next, the text conversion unit 313 sets the layer corresponding to the node of interest as a layer of interest (step S313). In this case, the A unit layer corresponding to the A unit 130 is set as a layer of interest. Thereafter, the text conversion unit 313 returns the process to step S303, and repeats step S303 and the subsequent steps.

When it is determined in step S308 that there is no layer corresponding to the node of interest (NO in step S308), the text conversion unit 313 next determines whether there is a part node that has not yet been focused on among the part nodes in the layer of interest (step S309). Here, when it is determined that there is a part node that has not yet been focused on (YES in step S309), the process returns to step S307, and repeats step S307 and the subsequent steps. Then, when the text conversion unit 313 determines that there is no part node that has not yet been focused on among the part nodes in the layer of interest (NO in step S309), the process proceeds to step S310.

Next, the text conversion unit 313 determines whether there is a part node that has not yet been focused on among the part nodes in the layer higher than the current layer of interest (step S310). When the current layer of interest is the lower layer, the higher layer means the middle layer and the upper layer. Here, when it is determined that there is a part node that has not yet been focused on in the layer higher than the current layer of interest (YES in step S310), the text conversion unit 313 next sets part nodes that have not yet been focused on one by one in order from the part node that has not yet been focused on in the layer closer to the current layer of interest among the part nodes that have not yet been focused on in the layers higher than the current layer of interest (step S311).

Next, the text conversion unit 313 determines whether there is a layer corresponding to the node of interest (step S312). When it is determined that there is a layer corresponding to the node of interest (YES in step S312), the process proceeds to step S313. On the other hand, when it is determined that there is no layer corresponding to the node of interest (NO in step S312), the text conversion unit 313 returns the process to step S310, and repeats step S310 and the subsequent steps.

Thereafter, in step S310, when the text conversion unit 313 determines that there is no part node that has not yet been focused on in the layer higher than the current layer of interest (NO in step S310), the hierarchical structure circuit text conversion process ends.

According to the hierarchical structure circuit text conversion process, it is possible to generate a circuit text including Text for each layer based on the graph data structure corresponding to each layer of the circuit constituting the apparatus 100.

Referring back to FIG. 3, the description will continue. After the circuit text is generated in step S3, the vector conversion unit 314 next generates circuit vector data by converting the circuit text into a vector, and stores the circuit vector data in the circuit vector DB 324 (step S4).

Next, the inquiry statement reception unit 315 receives an inquiry statement related to the circuit constituting the designed apparatus from the user using the terminal device 20 (step S5).

Next, the prompt generation unit 316 generates a prompt corresponding to the inquiry from the user, and the context generation unit 317 reads circuit vector data corresponding to the inquiry from the user from the circuit vector DB 324 and generates a context (step S6).

Next, the answer statement acquisition unit 318 inputs the prompt and the context to the language processing model 325, acquires an answer statement to the inquiry statement from the language processing model 325, and transmits the answer statement to the terminal device 20 (step S7).

Next, the terminal device 20 displays the answer statement to the inquiry statement, and presents the answer statement to the user (step S8). The above is an explanation of the electronic design supporting process performed by the electronic design supporting system 10.

According to the electronic design supporting process described above, in response to an inquiry statement from a user regarding the circuit constituting the apparatus (e.g., Does the A unit conform to the specifications? or Does the B board satisfy the constraints?), an answer statement output from the language processing model 325 in natural language (e.g. The conforms to the specifications. or The B board satisfies the constraints.) can be obtained. In addition, by generating the circuit text obtained by converting the link data into a text based on the graph data structure, the specification statement, and the constraint statement, it is possible to improve the accuracy of the answer provided by the language processing model 325. As a result, the user can easily grasp the details of the entire designed apparatus and each circuit, and it is possible to reduce the man-hours required for design and prevent rework caused by missing or overlooking design constraints.

<Method of Reading Specification Statement and Constraint Statement from Specification/Constraint DB 323 in Hierarchical Structure Circuit Text Conversion Process 33>

The specification statement and the constraint statement can be read from the specification/constraint DB 323, for example, by a data base (DB) method or a retrieval augmented generation (RAG) method.

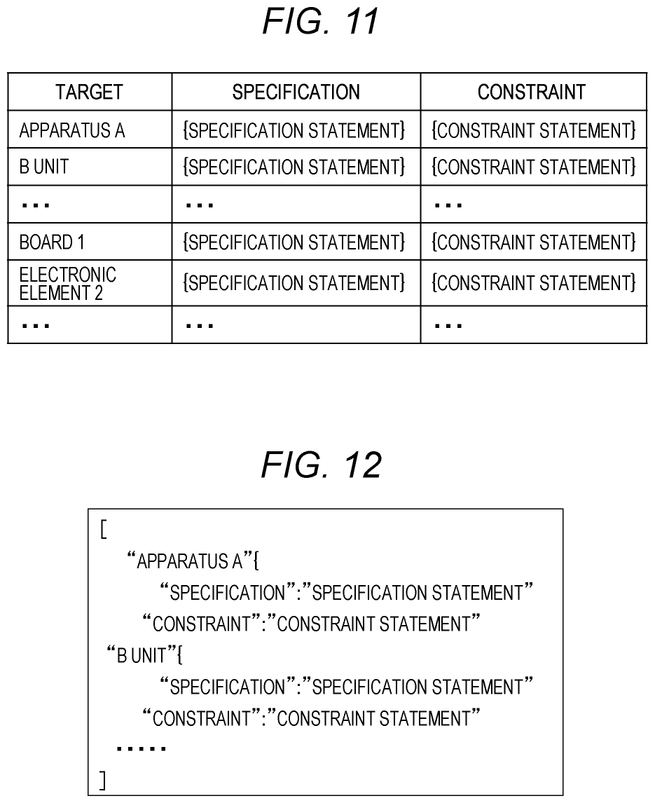

FIG. 11 illustrates an example of a data format of a specification statement and a constraint statement in the DB method. FIG. 12 illustrates an example of a result of reading from the specification/constraint DB 323.

In the DB method, as illustrated in FIG. 11, a specification statement and a constraint statement are stored in association with each other, for each apparatus, each unit, each board, and each electronic element, in the specification/constraint DB 323. Then, as the hierarchical structure circuit text conversion process 33, an apparatus name, a unit name, a board name, an electronic element name, and the like arranged in the layer of interest are designated as read targets with respect to the specification/constraint DB 323, thereby acquiring a read result in which a specification statement and a constraint statement corresponding to each read target are described as illustrated in FIG. 12. RDB, NoSQL, or the like is adopted as a DB type.

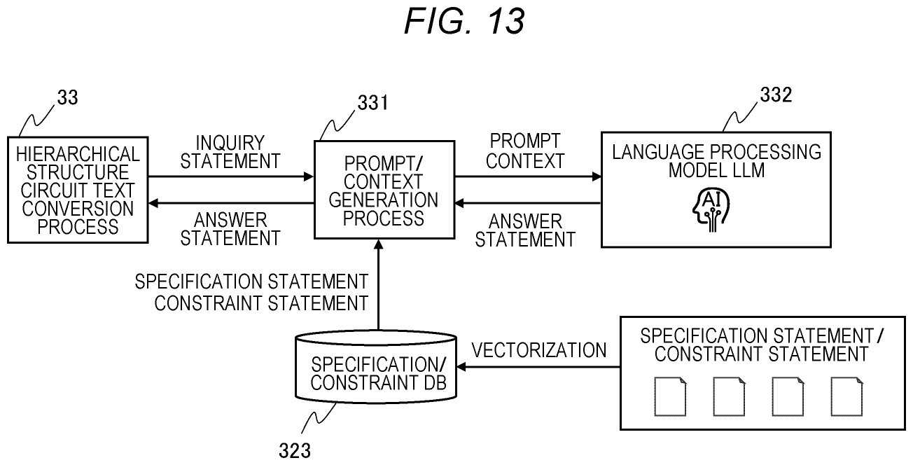

FIG. 13 illustrates an outline of reading a specification statement and a constraint statement from the specification/constraint DB 323 in a case where the RAG method is adopted.

In the RAG method, specification statements and constraint statements corresponding to apparatuses, units, boards, and electronic elements are converted into vectors and stored in the specification/constraint DB 323. Then, as the hierarchical structure circuit text conversion process 33, an apparatus name, a unit name, a board name, an electronic element name, and the like arranged in the layer of interest are designated as read targets, and an inquiry statement for acquiring specifications and constraints thereof is generated. Next, as the prompt/context generation process 331, a prompt corresponding to the inquiry statement is generated, a context is generated by reading a specification statement and a constraint statement corresponding to the inquiry statement from the specification/constraint DB 323, and the context is output to the language processing model 332. Then, an answer statement in which a specification statement and a constraint statement corresponding to each read target are described, the answer statement corresponding to the inquiry statement, is acquired from the language processing model 332. Note that the language processing model 332 illustrated in FIG. 13 may be identical to or different from the language processing model 325 illustrated in FIG. 1.

The present invention is not limited to the above-described embodiment, and various modifications can be made. For example, the above-described embodiment has been described in detail in order to explain the present invention in an easy-to-understand manner, and is not necessarily limited to having all the configurations described above. In addition, a part of a configuration of one embodiment can be replaced with or added to a configuration of another embodiment.

What is claimed is:

1. An electronic design supporting device that supports designing a circuit constituting an apparatus, the electronic design supporting device comprising:
a link data conversion unit that converts design data of the circuit into link data representing a connection relationship between parts arranged in the circuit;
a text conversion unit that converts the link data together with at least one of a specification statement and a constraint statement related to the circuit into a text to generate a circuit text;
a vector conversion unit that converts the circuit text into a vector to generate circuit vector data;
a circuit vector database that stores the circuit vector data;
an inquiry statement reception unit that receives an inquiry statement regarding the circuit;
a prompt generation unit that generates a prompt corresponding to the inquiry statement;
a context generation unit that generates a context by reading the circuit vector data corresponding to the circuit and related to a content of the inquiry statement from the circuit vector database; and
an answer statement acquisition unit that acquires an answer statement corresponding to the inquiry statement by inputting the prompt and the context to a language processing model.

2. The electronic design supporting device according to claim 1, wherein
the link data conversion unit generates a graph data structure including part nodes, terminal nodes, and wiring nodes for each layer of the circuit as the link data, and
the text conversion unit generates the circuit text based on the graph data structure for each layer of the circuit.

3. The electronic design supporting device according to claim 1, wherein
the link data conversion unit converts a part list and a net list as the design data of the circuit into the link data.

4. The electronic design supporting device according to claim 1, wherein
the text conversion unit reads at least one of the specification statement and the constraint statement related to the circuit from a specification/constraint database in which specification statements and constraint statements are stored.

5. The electronic design supporting device according to claim 4, wherein
the text conversion unit reads at least one of the specification statement and the constraint statement related to the circuit from the specification/constraint database by adopting a database method or a retrieval augmented generation (RAG) method.

6. An electronic design supporting method performed by an electronic design supporting device that supports designing a circuit constituting an apparatus, the electronic design supporting method comprising:
by the electronic design supporting device,
converting design data of the circuit into link data representing a connection relationship between parts arranged in the circuit;
converting the link data together with at least one of a specification statement and a constraint statement related to the circuit into a text to generate a circuit text;
converting the circuit text into a vector to generate circuit vector data, and storing the circuit vector data in a circuit vector database;
receiving an inquiry statement regarding the circuit;
generating a prompt corresponding to the inquiry statement;
generating a context by reading the circuit vector data corresponding to the circuit and related to a content of the inquiry statement from the circuit vector database; and
acquiring an answer statement corresponding to the inquiry statement by inputting the prompt and the context to a language processing model.
